(19) United States
(12) Patent Application Publication
(10) Pub. No.: US 2021/0296803 A1
(43) Pub. Date: Sep. 23, 2021

(54) CONVERSION BOARD FOR PRINTER CIRCUIT BOARD AND PACKAGING STRUCTURE THEREOF

(71) Applicant: CHIEN HWA COATING TECHNOLOGY, INC., HSINCHU CITY (TW)

(72) Inventors: YULUNG TSAO, HSINCHU CITY (TW); YIWEI LIN, HSINCHU CITY (TW); CHUNCHEN CHEN, HSINCHU CITY (TW)

(21) Appl. No.: 16/884,435

(22) Filed: May 27, 2020

(30) Foreign Application Priority Data
Mar. 19, 2020 (TW) 109109167

(51) Int. Cl. H01R 12/51; H01R 12/71; B41J 2/335

(52) U.S. Cl. CPC H01R 12/51; B41J 2/33535; H01R 12/716

(57) ABSTRACT

The present invention provides a conversion board for printing circuit board and the packaging structure thereof, which is disposed on a plurality of first joint parts of a board member. A plurality of first package pin members are disposed below a first circuit board. The plurality of first package pin members are connected electrically to the corresponding plurality of first joint parts, respectively. The conversion board is disposed on the first circuit board. The conversion board uses a plurality of second joint parts to connect electrically to the plurality of first package pin members. A plurality of second package pin members are disposed below a second circuit board. The plurality of second package pin members are connected electrically to the corresponding plurality of second joint parts, respectively.

### FIELD OF THE INVENTION

The present invention relates generally to a conversion board for printer circuit board and the packaging structure thereof, and particularly to a conversion structure capable of converting circuit boards with different sizes and different pins.

### BACKGROUND OF THE INVENTION

As technologies and commerce develop, invoices re receipts are required while paying a bill. Hence, a printer is included in a cashier. In particular, a heat sensitive printer (or a thermal printer) is a popular product widely adopted in retail, catering, and transportation businesses for printing receipts, price tags, or transportation details. As the applications of printers are extended, the types of printing media adopted by users vary. Since the structures of thermal printers can be made small, they are extensively adopted. Thermal printers uses thermal paper (or called heat sensitive paper).

The thermal paper adopts a chemical material coated thereon so that the color of the paper can be changed after being heated. No ink is required in the process. The thermal paper can be used in a thermal printer disposed in a lightweight and small-sized device such as a fax machine, an addometer, a cashier, and a credit-card terminal for reducing the cost.

The surface of the thermal paper will be coated with solid dye and appropriate base material, such as fluorane-type invisible dye and octadecylphosphonic acid. When the base material is heated to the melting point, the dye will react with the acid material and turn to the colored state. The base material can be cooled down easily, and the colored state of the dye will be stored in a sub-stable state. After a period, the color still will fade. Thereby, the thermal paper is only suitable for applications not requiring long-term storage.

Normally, the dye will turn to black after being heated. But sometimes, dyes turning to blue or red will be adopted instead. An open heat source, such flames, will change the color of the paper. Rubbing the paper rapidly will provide sufficient thermal energy to generate a colored mark. Right before the thermal paper roll is running up, a red stripe will appear on the edge for reminding the user of replacing the paper roll.

The thermal printing head of the thermal printer according to the prior art is connected to the thermal printer via a flat flexible cable disposed on one end of the base board. To avoid obstructing delivery of paper and considering neatness, normally the flat flexible cable will be hidden inside the case. This arrangement makes it impossible or difficult to replace the printing head of the thermal printer. In addition, the printer according to the prior art can accommodate a one-size printing circuit board. To use paper with a different size, another printer must be used instead, leading to extra efforts and costs. Thereby, it is urged to have a replacement method capable of converting to circuit boards with different sizes rapidly, as well as a structure design with uniformly distributed pins.

To solve the above problems according to the prior art, the present invention provides a conversion board for printing circuit board and the packaging structure thereof. According to the present invention, a plurality of package pin members are disposed below a first and a second circuit board. The conversion board is disposed on the first circuit board. The second circuit boards is inserted to the conversion board. By using the conversion board to convert the first and second circuit boards, printing circuit boards with different package pins and sizes can be installed to a printer.

### SUMMARY

An objective of the present invention is to provide a conversion board for printing circuit board and the packaging structure thereof. A plurality of package pin members are disposed below a first and a second circuit board. The conversion board is disposed on the first circuit board. The second circuit boards is inserted to the conversion board. By using the conversion board to convert the first and second circuit boards, printing circuit boards with different package pins and sizes can be installed to a printer.

To achieve the above objective and efficacy, the present invention provides a conversion board for printing circuit board and the packaging structure thereof disposed on a plurality of first joint parts of a board member. The conversion board for printing circuit board and the packaging structure thereof comprise a first circuit board, a conversion board, and a second circuit board. A bottom of said first circuit board disposed a plurality of first package pin members. The plurality of first package pin members are connected electrically to the corresponding plurality of first joint parts, respectively. The conversion board is disposed on the first circuit board. A plurality of second joint parts are disposed on the conversion board. The plurality of second joint parts are connected electrically to the plurality of first package pin members. A bottom of said second circuit board disposed a plurality of second package pin members. The plurality of second package pin members are connected electrically to the corresponding plurality of second joint parts, respectively. By using the conversion board to convert the first and second circuit boards, printing circuit boards with different package pins and sizes can be installed to a printer.

According to an embodiment of the present invention, the plurality of first package pin members are a plurality of pillar-shaped members spaced at intervals, respectively. The plurality of pillar-shaped members and the plurality of first joint parts are connected electrically.

According to an embodiment of the present invention, the plurality of first package pin members are a plurality of ball-shaped members spaced at intervals, respectively. The plurality of ball-shaped members and the plurality of first joint parts are connected electrically.

According to an embodiment of the present invention, the plurality of second package pin members are a plurality of pillar-shaped members spaced at intervals, respectively. The plurality of pillar-shaped members and the plurality of second joint parts are connected electrically.

According to an embodiment of the present invention, the plurality of second package pin members are a plurality of ball-shaped members spaced at intervals, respectively. The plurality of ball-shaped members and the plurality of second joint parts are connected electrically.

According to an embodiment of the present invention, a first interval between the first package pin members is greater than a second interval between the second package pin members.

According to an embodiment of the present invention, the number of the plurality of first package pin members is identical to the number of the plurality of package pin members.

According to an embodiment of the present invention, the conversion board for printing circuit board and the packaging structure thereof further comprise a fixing member disposed on the first circuit board. The fixing member includes a body and a projective member. The projective member is disposed on the body. The second circuit board is sandwiched between the projective member and the first circuit board.

According to an embodiment of the present invention, the conversion board for printing circuit board and the packaging structure thereof further comprise at least one threaded member passing through at least one first hole on the outer edge of the fixing member and a second hole on the first circuit board.

According to an embodiment of the present invention, the conversion board for printing circuit board and the packaging structure thereof further comprise a heating device disposed on and connected electrically to the second circuit board.

### BRIEF DESCRIPTION OF THE DRAWINGS

FIG. 1 shows a structural schematic diagram according to an embodiment of the present invention;

FIG. 2A shows a structural schematic diagram of the first pins according to an embodiment of the present invention;

FIG. 2B shows a structural schematic diagram of the second pins according to an embodiment of the present invention; and

FIG. 3A to 3C show structural schematic diagrams of the fixing members according to an embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The present invention provides a conversion board for printing circuit board and the packaging structure thereof. A plurality of package pin members are disposed below a first and a second circuit board. The conversion board is disposed on the first circuit board. The second circuit boards is inserted to the conversion board. By using the conversion board to convert the first and second circuit boards, printing circuit boards with different package pins and sizes can be installed to a printer.

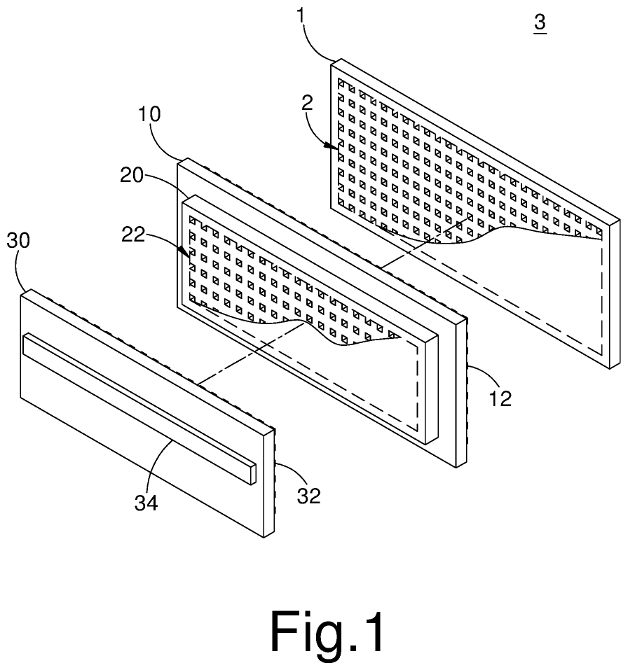

Please refer to FIG. 1, which shows a structural schematic diagram according to an embodiment of the present invention. As shown in the figure, the present invention provides a conversion board for printing circuit board and the packaging structure thereof 3 disposed on a plurality of first joint parts 2 of a board member 1. The conversion board for printing circuit board and the packaging structure thereof 3 comprise a first circuit board 10, a conversion board 20, and a second circuit board 30.

Please refer again to FIG. 1. As shown in the figure, according to the present embodiment, a plurality of first package pin members 12 are disposed below the first circuit board 10. The plurality of first package pin members 12 correspond to the plurality of first joint parts 2 of the board member 1, respectively, and are connected electrically (for example, contacting by insertion) on the plurality of first joint parts 2. The conversion board 20 is disposed on the first circuit board 10. The connection method can be gluing the conversion board 20 to the first circuit board 10 by a paste or soldering the conversion board 20 on the first circuit board 10. A plurality of second joint parts 22 are disposed on the conversion board 20. The plurality of second joint parts 22 are connected electrically to the plurality of first package pin members 12 from the inner side of the conversion board 20. A plurality of second package pin members 32 are disposed below the second circuit board 30. The plurality of second package pin members 32 correspond to the plurality of second joint parts 22 of the board member 1, respectively, and are connected electrically (for example, contacting by insertion) on the plurality of second joint parts 22.

According to the present embodiment, a heating device 34 is further disposed on the second circuit board 30. The heating device 34 is connected electrically to second circuit board 30 for receiving electrical energy and control signals, forming a thermal printing head (TPH). The TPH can generate heat by using the heating device 34 for heating the thermal paper according to the prior art.

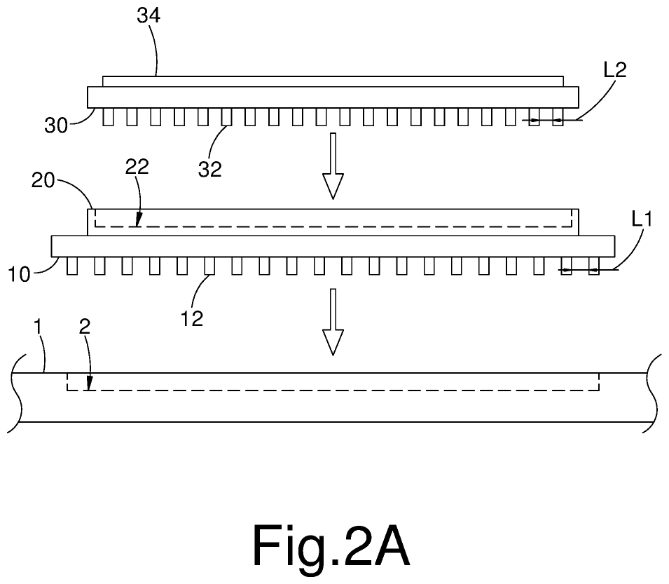

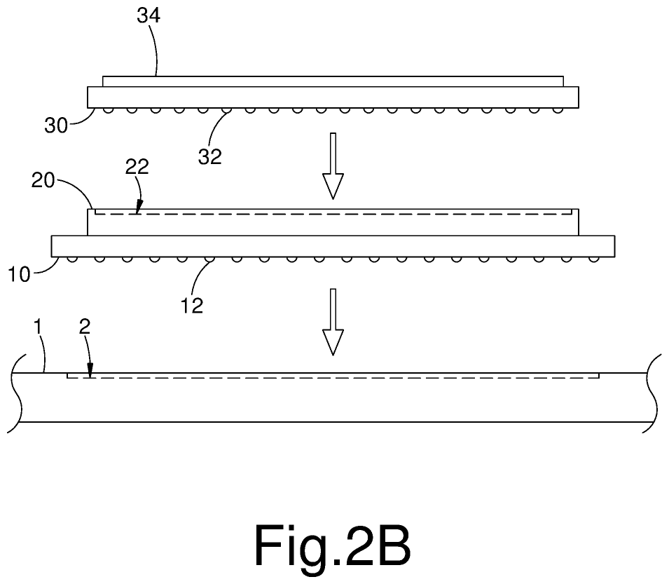

Please refer to FIG. 2A, which shows a structural schematic diagram of the first pins according to an embodiment of the present invention. As shown in the figure, according to the present embodiment, the plurality of first package pin members 12 are pillar-shaped members. The plurality of pillar-shaped members are disposed at intervals of a first interval L1 (only one of them is labeled) for forming a pin grid array (PGA) pin structure. The plurality of pillar-shaped members and the plurality of first joint parts 2 are connected electrically. According to the present embodiment, the plurality of second package pin members 32 are pillar-shaped members. The plurality of pillar-shaped members are disposed at intervals of a second interval L2 (only one of them is labeled) for forming a PGA pin structure. The plurality of pillar-shaped members and the plurality of second joint parts 22 are connected electrically.

Please refer to FIG. 2B, which shows a structural schematic diagram of the second pins according to an embodiment of the present invention. As shown in the figure, according to the present embodiment, the plurality of first package pin members 12 are ball-shaped members. The plurality of pillar-shaped members are disposed at intervals of a first interval L1 (only one of them is labeled) for forming a ball grid array (BGA) pin structure. The plurality of ball-shaped members and the plurality of first joint parts 2 are connected electrically. According to the present embodiment, the plurality of second package pin members 32 are ball-shaped members. The plurality of ball-shaped members are disposed at intervals of a second interval L2 (only one of them is labeled) for forming a BGA pin structure. The plurality of ball-shaped members and the plurality of second joint parts 22 are connected electrically.

According to the present embodiment, the plurality of first package pin members 12 and the plurality of second package pin members 32 can be different package pins. For example, the plurality of first package pin members 12 are PGA package while the plurality of second package pin members 32 are BGA package. The conversion board 20 converts signals to the plurality of first package pin members 12 and the plurality of second package pin members 32. Thereby, the conversion board for printing circuit board and the packaging structure thereof 3 can achieve the efficacy of converting different package pins.

According to the present embodiment, the first interval L1 of the first package pin member 12 is greater than the second interval L2 of the second package pin member 32. In addition, the number of the plurality of first package pin members 12 is identical to the number of the plurality of second package pin members so that the conversion board for printing circuit board and the package structure thereof 3 can achieve the efficacy of converting printing circuit boards with different sizes.

According to the present embodiment, the first circuit board 10 is disposed on the plurality of first joint parts 2 of the board member 1. The plurality of first package pin members 12 of the first circuit board 10 are connected electrically to the corresponding plurality of first joint parts 2, respectively. The conversion board 20 is then disposed on the first circuit board 10. The plurality of second package pin members 32 of the second circuit board 30 are connected electrically to the corresponding plurality of second joint parts 22, respectively. Thereby, a structure for converting the first circuit board 10 and the second circuit board 30 is formed and hence achieving the efficacy of converting printing circuit boards with different sizes.

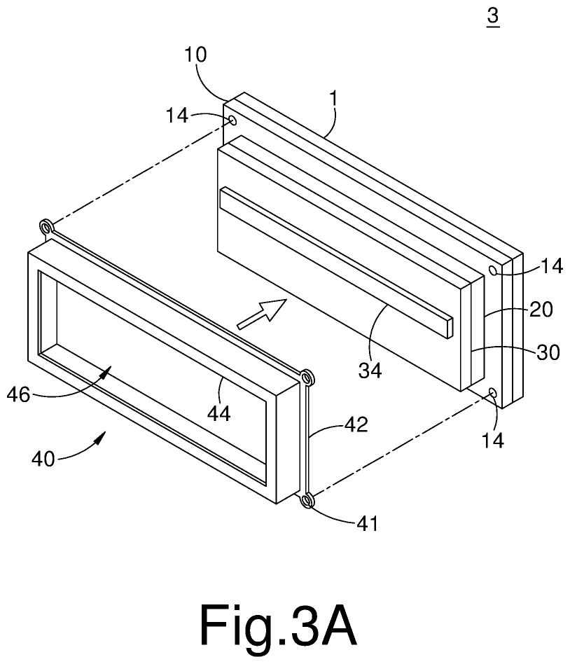

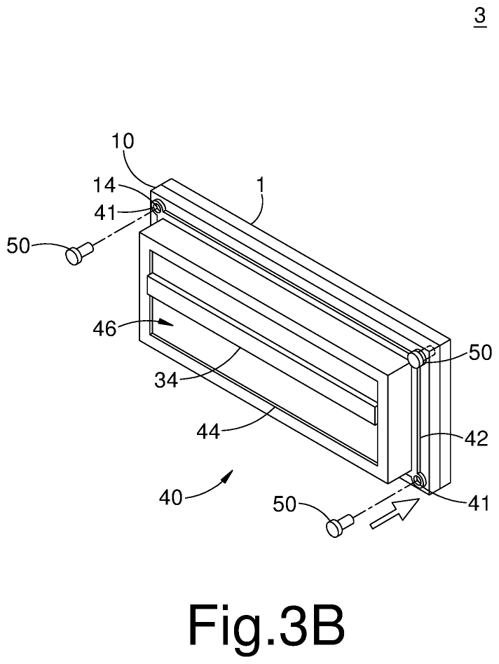

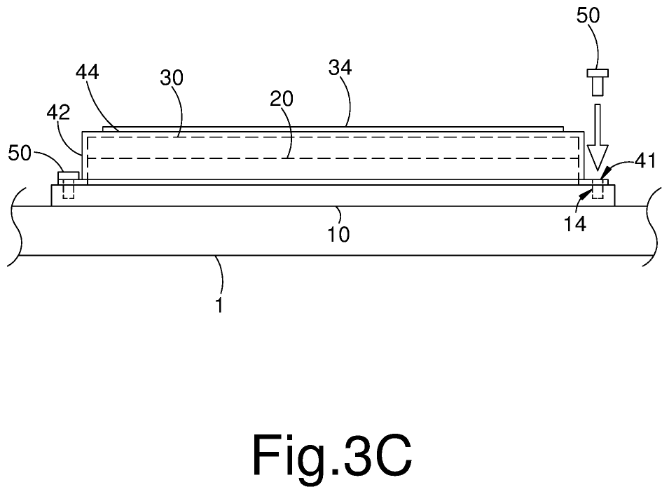

Please refer to FIG. 3A to 3C, which show structural schematic diagrams of the fixing members according to an embodiment of the present invention. As shown in the figures, according to the present embodiment, a fixing member 40 is disposed on the first circuit board 10. The fixing member 40 includes a body 42, an opening 46, and a projective member 44. The opening 46 passes through the body 42. The projective member 44 is formed between the opening 46 and the body 42 such that the projective member 44 is disposed on the body 42. The second circuit board 30 is sandwiched between the projective member 44 and the first circuit board 10 for limiting the location of the second circuit board 30 and avoiding it from moving. The heating device 34 is disposed on the second circuit board 30 and projecting to the opening 46 such that the heating device 34 can contact printing media, for example, the thermal paper. The connection and operation of other components according to the present embodiment are identical to the above embodiment. Hence, the details will not be described again.

The present embodiment further comprises at least one threaded member 50 passing though at least one first hole 42 disposed on the outer edge of the fixing member 40. The at least one threaded member 50 then passes through a second hole 14 disposed on the first circuit board 10. The at least one threaded member 50 fixes the fixing member 40 on the first circuit board 10 for avoiding it from moving.

According to the present embodiment, the first circuit board 10 is disposed on the plurality of first joint parts 2 of the board member 1. The plurality of first package pin members 12 of the first circuit board 10 are connected electrically to the corresponding plurality of first joint parts 2, respectively. The conversion board 20 is then disposed on the first circuit board 10. The plurality of second package pin members 32 of the second circuit board 30 are connected electrically to the corresponding plurality of second joint parts 22, respectively, and hence forming the structure for converting the first circuit 10 and the second circuit board 30 and achieving the efficacy of converting printing circuit boards with different sizes. Furthermore, the fixing member 50 is disposed on the first circuit board 10 for liming the location of the second circuit board 30 and avoiding it from moving.

To sum up, the present invention provides a conversion board for printing circuit board and the packaging structure thereof. According to the present invention, a plurality of package pin members are disposed below a first and a second circuit board. The conversion board is disposed on the first circuit board. The second circuit boards is inserted to the conversion board. By using the conversion board to convert the first and second circuit boards, printing circuit boards with different package pins and sizes can be installed to a printer. A fixing member is further used to clip and limit the location of the circuit boards, keeping them from moving. In addition, the problem of replacing the hidden flat flexible cable inside the case according to the prior art can be solved as well.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. A conversion board for printing circuit board and the package structure thereof, disposed on a plurality of first joint parts of a board member, and comprising:
a first circuit board, a bottom of said first circuit board disposed a plurality of first package pin members, said plurality of first package pin members connected electrically to said corresponding plurality of first joint parts, respectively;
a conversion board disposed on said first circuit board, a plurality of second joint parts disposed on said conversion board, and said plurality of second joint parts connected electrically to said plurality of first package pin members; and
a second circuit board, a bottom of said second circuit board disposed a plurality of second package pin members, said plurality of second package pin members connected electrically to said corresponding plurality of second joint parts, respectively.

2. The conversion board for printing circuit board and the package structure thereof of claim 1, wherein said plurality of first package pin members are a plurality of pillar-shaped members disposed at intervals and connected electrically to said plurality of first joint parts.

3. The conversion board for printing circuit board and the package structure thereof of claim 1, wherein said plurality of first package pin members are a plurality of ball-shaped members disposed at intervals and connected electrically to said plurality of first joint parts.

4. The conversion board for printing circuit board and the package structure thereof of claim 1, wherein said plurality of second package pin members are a plurality of pillar-shaped members disposed at intervals and connected electrically to said plurality of second joint parts.

5. The conversion board for printing circuit board and the package structure thereof of claim 1, wherein said plurality of second package pin members are a plurality of ball-shaped members disposed at intervals and connected electrically to said plurality of second joint parts.

6. The conversion board for printing circuit board and the package structure thereof of claim 1, wherein a first interval between said first package pin members is greater than a second interval between said second package pin members.

7. The conversion board for printing circuit board and the package structure thereof of claim 1, wherein the number of said plurality of first package pin members is greater than the number of said plurality of second package pin members.

8. The conversion board for printing circuit board and the package structure thereof of claim 1, comprising a fixing member, disposed on said first circuit board, including a body and a projective member, said projective member disposed on said body, and said second circuit board sandwiched between said projective member and said first circuit board.

9. The conversion board for printing circuit board and the package structure thereof of claim 8, comprising at least one threaded member passing through at least one first hole on the outer edge of said fixing member and at second hole of said first circuit board.

10. The conversion board for printing circuit board and the package structure thereof of claim 1, comprising a heating device disposed on and connected to said second circuit board.
